(19) United States
(12) Patent Application Publication
(10) Pub. No.: US 2025/0365936 A1
(43) Pub. Date: Nov. 27, 2025

(54) SEMICONDUCTOR DEVICES

(71) Applicant: Samsung Electronics Co., Ltd., Suwon-si (KR)

(72) Inventor: Sinyeon Kim, Suwon-si (KR)

(21) Appl. No.: 19/204,817

(22) Filed: May 12, 2025

(30) Foreign Application Priority Data
May 22, 2024 (KR) 10-2024-0066740

(51) Int. Cl. H10B 12/00; H10D 30/63; H10D 62/17; H10D 62/80; H10D 64/27

(52) U.S. Cl. CPC H10B 12/315; H10B 12/482; H10B 12/485; H10B 12/488; H10D 30/63; H10D 62/292; H10D 62/875; H10D 64/514; H10B 12/05

(57) ABSTRACT

A semiconductor device comprising: a bit line extending in a first horizontal direction on a substrate; a channel layer on the bit line, including an oxide semiconductor material that includes indium (In), a first vertical portion, a horizontal portion on the first vertical portion, and a second vertical portion on the horizontal portion; a gate dielectric layer in contact with a first sidewall of the first vertical portion of the channel layer and a lower surface of the horizontal portion of the channel layer; a word line on an inner sidewall and a lower surface of the gate dielectric layer, extending in a second horizontal direction; contact structures, wherein at least one of the contact structures is in contact with the horizontal portion and the second vertical portion of the channel layer; and a capacitor structure on the at least one of the contact structures.

### CROSS-REFERENCE TO RELATED APPLICATIONS

This application is based on and claims priority under 35 U.S.C. § 119 to Korean Patent Application No. 10-2024-0066740, filed on May 22, 2024, in the Korean Intellectual Property Office, the disclosures of which are incorporated by reference herein in their entirety.

### BACKGROUND OF THE INVENTION

The inventive concept may relate to semiconductor devices, and more particularly, to semiconductor devices including a vertical channel transistor.

To meet performance needs and economic feasibility, it may be needed to increase the degree of integration of semiconductor devices. In particular, the degree of integration of memory devices may be an important factor in determining the economic feasibility of a product. Since the degree of integration of a two (2)-dimensional memory device may be mainly affected by the area occupied by a unit memory cell, it may be influenced by the level of micro-pattern formation technology. However, expensive equipment may be needed to form fine patterns, and the area of a chip die is limited. Therefore, although the degree of integration of 2-dimensional memory devices is increasing, the degree of integration may still be limited.

### SUMMARY OF THE INVENTION

The inventive concept may provide a semiconductor device capable of improving product reliability by enhancing electrical characteristics.

In addition, the technical goals to be achieved by the inventive concept are not limited to the technical goals mentioned above, and other technical goals may be clearly understood by one of ordinary skill in the art from the following descriptions.

According to an aspect of the inventive concept, there is provided a semiconductor device comprising: a substrate; a bit line extending in a first horizontal direction on the substrate; a channel layer on the bit line, wherein the channel layer includes an oxide semiconductor material that includes indium (In), and wherein the channel layer includes a first vertical portion, a horizontal portion on the first vertical portion, and a second vertical portion on the horizontal portion; a gate dielectric layer in contact with a first sidewall of the first vertical portion of the channel layer and a lower surface of the horizontal portion of the channel layer; a word line on an inner sidewall and a lower surface of the gate dielectric layer, wherein the word line extends in a second horizontal direction that intersects with the first horizontal direction; contact structures, wherein at least one of the contact structures is in contact with the horizontal portion and the second vertical portion of the channel layer; and a capacitor structure on the at least one of the contact structures, wherein the first horizontal direction and the second horizontal direction are parallel with an upper surface of the substrate.

According to another aspect of the inventive concept, there is provided a semiconductor device comprising: a substrate; a bit line extending in a first horizontal direction on the substrate; a mold layer on the bit line, wherein the mold layer includes a mold opening; a channel layer in the mold opening, wherein the channel layer includes a horizontal portion, a first vertical portion below a first end of the horizontal portion, and a second vertical portion above a second end of the horizontal portion that is opposite to the first end of the horizontal portion in the first horizontal direction, and wherein the channel layer includes IGZO (InGaZnOx); a gate dielectric layer below the channel layer in the mold opening, wherein the gate dielectric layer includes a high-k material; a word line below the gate dielectric layer in the mold opening, wherein the word line extends in a second horizontal direction that intersects with the first horizontal direction; a contact structure in contact with an upper surface of the mold layer, an upper surface of the horizontal portion of the channel layer, and an outer sidewall of the second vertical portion of the channel layer; and a capacitor structure on the contact structure wherein the first horizontal direction and the second horizontal direction are parallel with an upper surface of the substrate.

According to another aspect of the inventive concept, there is provided a semiconductor device comprising: a substrate; a bit line including a horizontal extension that extends in a first horizontal direction on the substrate and a vertical protrusion that protrudes from the horizontal extension in a vertical direction; a channel layer comprising a first vertical portion that extends in the vertical direction on the vertical protrusion of the bit line, a horizontal portion that extends in the first horizontal direction on an upper surface of the first vertical portion, and a second vertical portion that extends in the vertical direction on an upper surface of the horizontal portion; a gate dielectric layer in contact with an inner sidewall of the first vertical portion of the channel layer and a lower surface of the horizontal portion of the channel layer; a word line on the gate dielectric layer, wherein the word line extends in a second horizontal direction that intersects the first horizontal direction; a mold layer in contact with an outer sidewall of the first vertical portion of the channel layer and a sidewall of the horizontal portion of the channel layer; a contact structure in contact with the mold layer, the horizontal portion of the channel layer, and the second vertical portion of the channel layer; a dielectric spacer on sidewalls of the contact structure, wherein the dielectric spacer includes a plurality of spacer layers; and a capacitor structure on the contact structure, wherein the first horizontal direction and the second horizontal direction are parallel with an upper surface of the substrate, and wherein the vertical direction is perpendicular to the upper surface of the substrate.

### BRIEF DESCRIPTION OF THE DRAWINGS

Embodiments of the inventive concept will be more clearly understood from the following detailed description taken in conjunction with the accompanying drawings in which:

FIG. 1 is a layout view of a semiconductor device according to some embodiments;

FIG. 2 is an enlarged layout view of a cell array area of FIG. 1;

FIG. 3 is a cross-sectional view taken along a line A1-A1′ of FIG. 2;

FIG. 4 is an enlarged view of a portion CX of FIG. 3;

FIGS. 5 and 6 are cross-sectional views showing semiconductor devices according to some embodiments;

FIGS. 7 to 22 are cross-sectional views showing, in a process sequence, a method of manufacturing a semiconductor device, according to some embodiments; and

FIG. 23 is a configuration diagram showing a system including a semiconductor device according to some embodiments.

### DETAILED DESCRIPTION OF THE INVENTION

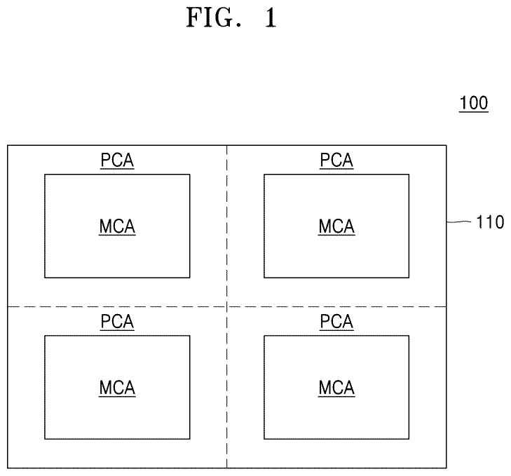

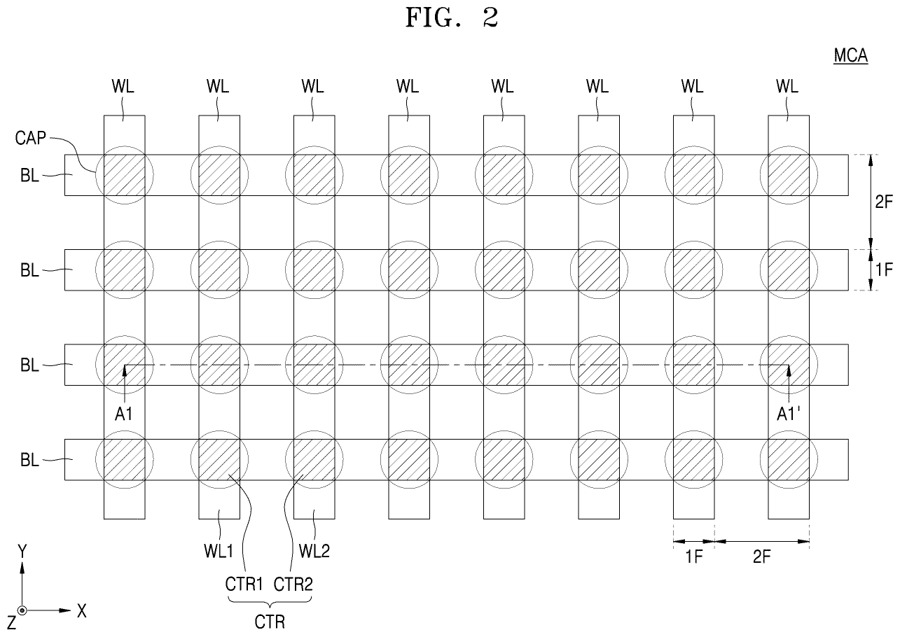

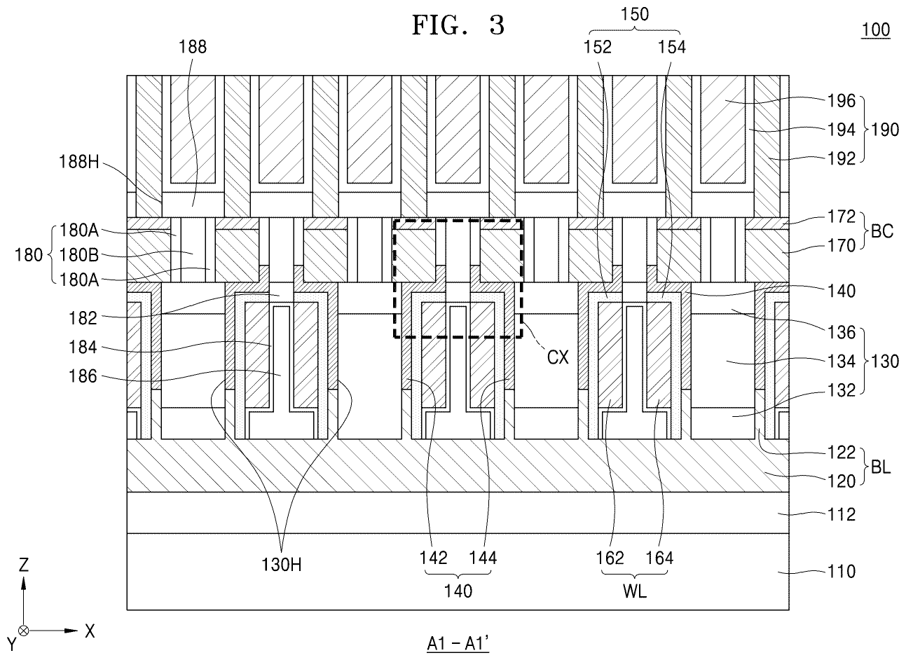

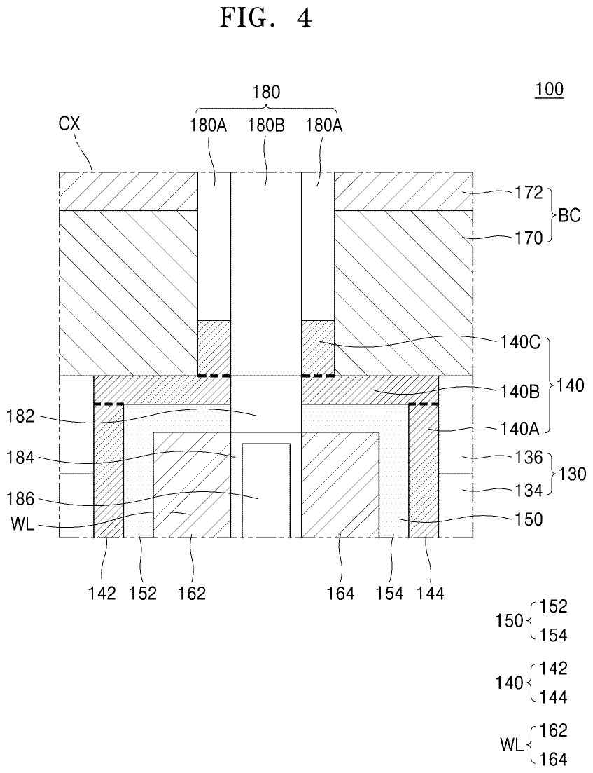

FIG. 1 is a layout view of a semiconductor device according to some embodiments. FIG. 2 is an enlarged layout view of a cell array area of FIG. 1. FIG. 3 is a cross-sectional view taken along a line A1-A1′ of FIG. 2. FIG. 4 is an enlarged view of a portion CX of FIG. 3.

Referring to FIGS. 1 to 4 together, a semiconductor device 100 may include a substrate 110 including a cell array area MCA and a peripheral circuit area PCA.

As shown in FIG. 1, according to some embodiments, the cell array area MCA may be a memory cell region of a dynamic random access memory (DRAM) device, and the peripheral circuit area PCA may be a core area or a peripheral circuit area of a DRAM device. For example, the peripheral circuit area PCA may include a peripheral circuit transistor (not shown) for transmitting a signal and/or power to a memory cell array included in the cell array area MCA.

According to some embodiments, a peripheral circuit transistor (not shown) may configure various circuits, such as a command decoder, control logic, an address buffer, a row decoder, a column decoder, a sense amplifier, and a data input/output circuit.

As shown in FIG. 2, on the cell array area MCA of the substrate 110, a plurality of bit lines BL extending in a first horizontal direction (X direction) and a plurality of word lines WL extending in a second horizontal direction (Y direction) intersecting (crossing or overlapping) the first horizontal direction (X direction) may be arranged. For example, the first and second horizontal directions may be parallel with an upper surface of the substrate 110. The first and second horizontal directions may be perpendicular to each other. A plurality of cell transistors CTR may be arranged at the intersections of the plurality of bit lines BL and the plurality of word lines WL, respectively. A plurality of cell capacitors CAP may be arranged on the plurality of cell transistors CTR, respectively.

The plurality of word lines WL may include a first word line WL1 and a second word line WL2 alternately arranged in the first horizontal direction (X direction), and the plurality of cell transistors CTR may include a first cell transistor CTR1 and a second cell transistor CTR2 alternately arranged in the first horizontal direction (X direction). In other words, the first cell transistor CTR1 may be disposed on the first word line WL1, and the second cell transistor CTR2 may be disposed on the second word line WL2.

The first cell transistor CTR1 and the second cell transistor CTR2 may have mirror-image symmetric structures with respect to each other. For example, the first cell transistor CTR1 and the second cell transistor CTR2 may have a mirror-image symmetric structure around a center line (an imaginary center line) extending in the second horizontal direction (Y direction). For example, the first cell transistor CTR1 and the second cell transistor CTR2 may have mirror-image symmetric structures to each other with respect to the first horizontal direction (X direction).

According to some embodiments, the width of the plurality of bit lines BL in the second horizontal direction (Y direction) may be 1F, and the pitch (i.e., the sum of the width of one of patterns and the spacing between adjacent ones of the patterns) of the plurality of bit lines BL may be 2F (twice of 1F). Also, the width of the plurality of word lines WL in the first horizontal direction (X direction) may be 1F, and the pitch of the plurality of word lines WL may be 2F. Therefore, the unit area for forming one cell transistor CTR may be 4F². Therefore, since the cell transistor CTR may be a cross-point type that needs a relatively small unit area, the integration of the semiconductor device 100 may be improved.

As shown in FIG. 3, a lower dielectric layer 112 may be disposed on the substrate 110. According to some embodiments, the substrate 110 may include silicon, e.g., monocrystalline silicon, polycrystalline silicon, and/or amorphous silicon. According to some embodiments, the substrate 110 may include, for example, Ge, SiGe, SiC, GaAs, InAs, and/or InP. According to some embodiments, the substrate 110 may include a conductive region, e.g., a well doped with an impurity or a structure doped with an impurity. The lower dielectric layer 112 may include, for example, silicon oxide, silicon nitride, and/or a combination thereof, but is not limited thereto.

A bit line BL extending in the first horizontal direction (X direction) may be disposed on the lower dielectric layer 112. For example, the bit line BL may include Ti, TiN, Ta, TaN, W, WN, TiSiN, WSiN, polysilicon, and/or a combination thereof. A bit line dielectric layer (not shown) extending in the first horizontal direction (X direction) may be disposed on a sidewall of the bit line BL. For example, the bit line dielectric layer may fill the space between two adjacent bit lines BL and have the same height as the bit lines BL. The height (e.g., a vertical level) may be a relative location (e.g., distance) from a lower surface of the substrate 110 in a vertical direction (Z direction). A farther distance from the lower surface of the substrate 110 may be a higher height (e.g., a higher vertical level). A closer distance from the lower surface of the substrate 110 may be a lower height (e.g., a lower vertical level). The vertical direction (Z direction) may be perpendicular to the upper surface of the substrate 110. The vertical direction (Z direction) may be perpendicular to the first and second horizontal directions (X direction and Y direction).

According to some embodiments, the bit line BL may include a horizontal extension 120 extending in a first horizontal direction (X direction) and a plurality of vertical protrusions 122 protruding from one horizontal extension 120 in the vertical direction (Z direction). Detailed descriptions thereof are given below.

A mold layer 130 may be disposed on the bit line BL and the bit line dielectric layer. The mold layer 130 may include a plurality of mold openings 130H. According to some embodiments, the mold layer 130 may include a plurality of mold dielectric layers stacked in the vertical direction (Z direction). For example, the mold layer 130 may include first, second, and third mold dielectric layers 132, 134, and 136. According to some embodiments, the first, second, and third mold dielectric layers 132, 134, and 136 may include different dielectric materials. In some embodiments, the first mold dielectric layer 132 and the third mold dielectric layer 136 may include the same material, and the second mold dielectric layer 134 may include a material different from (that constituting) the first mold dielectric layer 132 and the third mold dielectric layer 136. The embodiments of the materials included in first, second, and third mold dielectric layers 132, 134, and 136, however, are not limited to the embodiments mentioned above.

A plurality of channel layers 140 may be arranged on the inner walls (e.g., inner sidewalls) of the plurality of mold openings 130H. The inner walls (e.g., the inner sidewalls) of the mold opening 130H may refer to sidewalls of the mold layer 130 (exposed by the mold opening 130H). For example, an outer sidewall of the channel layer 140 (e.g., an outer sidewall of the first vertical portion 140A and an outer sidewall of the horizontal portion 140B) may be on the sidewall of the mold layer 130. According to some embodiments, the plurality of channel layers 140 may include an oxide semiconductor material. For example, the oxide semiconductor material may include indium (In). For example, the plurality of channel layers 140 may include InGaZnOₓ (IGZO), Sn-doped InGaZnOₓ (IGZO), W-doped InGaZnOₓ (IGZO), and/or InZnOₓ (IZO).

As shown in FIG. 4, in the semiconductor device 100 according to the inventive concept, the plurality of channel layers 140 nay each include a first vertical portion 140A, a horizontal portion 140B on the first vertical portion 140A, and a second vertical portion 140C on the horizontal portion 140B. The first vertical portion 140A may be disposed downward from one end of the horizontal portion 140B (e.g., a first end of the horizontal portion 140B in the first horizontal direction (X direction)), and the second vertical portion 140C may be disposed upward from the other end of the horizontal portion 140B (e.g., a second end of the horizontal portion 140B opposite to the first end of the horizontal portion 140B in the first horizontal direction (X direction)). In other words, the first vertical portion 140A and the second vertical portion 140C may not overlap each other in the vertical direction (Z direction). The first vertical portion 140A, the second vertical portion 140C, and the horizontal portion 140B may form a unitary structure. A unitary structure (e.g., the channel layer 140) herein may refer to a structure (e.g., a continuum) without a (visible) boundary between its sub-structures (e.g., The first vertical portion 140A, the second vertical portion 140C, and the horizontal portion 140B).

The sidewalls of first vertical portions 140A and horizontal portions 140B of the plurality of channel layers 140 may be arranged to contact on the inner walls (e.g., the inner sidewalls) of the plurality of mold openings 130H of the mold layer 130, and second vertical portions 140C may be arranged at a vertical level equal or higher than the upper surface (e.g., top surface) of the mold layer 130.

Also, on the inner walls (e.g., the inner sidewalls) of the plurality of mold openings 130H of the mold layer 130, the upper surface (e.g., uppermost surface) of the vertical protrusion 122 of the bit line BL may be disposed to contact the lower surface (e.g., lowermost surface) of the first vertical portion 140A. Also, one sidewall (e.g., a first sidewall) of the vertical protrusion 122 of the bit line BL may be disposed to contact the sidewall of the mold layer 130, and the other sidewall (e.g., a second sidewall opposite to the first sidewall in the first horizontal direction (X direction)) of the vertical protrusions 122 of the bit line BL may be disposed to contact the sidewall of a gate dielectric layer 150, as described below.

The gate dielectric layer 150 and the word line WL may be sequentially disposed on the inner wall of each of the plurality of channel layers 140. For example, the gate dielectric layer 150 may be disposed to contact one sidewall of the first vertical portion 140A and the lower surface of the horizontal portion 140B of the plurality of channel layers 140. The gate dielectric layer 150 may include a high-k dielectric material having a higher dielectric constant than silicon oxide. According to some embodiments, the gate dielectric layer 150 may have a dielectric constant from (about) 10 to (about) 25. For example, the gate dielectric layer 150 may include HfO₂, Al₂O₃, HfAlO₃, Ta₂O₃, TiO₂, and/or a combination thereof, but is not limited thereto.

Also, the word line WL may be disposed on the inner wall of the gate dielectric layer 150 and extend in the second horizontal direction (Y direction) crossing (intersecting or overlapping) the first horizontal direction (X direction). The word line WL may include, for example, Ti, TiN, Ta, TaN, W, WN, TiSiN, WSiN, polysilicon, and/or a combination thereof.

Inside one mold opening 130H, a channel layer 140, the gate dielectric layer 150, and the word line WL may form a pair and may be arranged to be spaced apart from each other in the first horizontal direction (X direction). In some embodiments, the channel layer 140 may include a first channel layer 142 and a second channel layer 144 that is spaced apart from and mirror-image symmetrical to the first channel layer 142 in the first horizontal direction (X direction)). The gate dielectric layer 150 may include a first gate dielectric layer 152 and a second gate dielectric layer 154 that is spaced apart from and mirror-image symmetrical to the first gate dielectric layer 152 in the first horizontal direction (X direction)). The word line WL may include a first word line 162 and a second word line 164 that is spaced apart from and mirror-image symmetrical to the first word line 162 in the first horizontal direction (X direction)). In detail, the first word line 162 may be disposed to face the first channel layer 142, and the second word line 164 may be disposed to face the second channel layer 144. The first word line 162 and the first channel layer 142 may be spaced apart from each other by the first gate dielectric layer 152 therebetween. The second word line 164 and the second channel layer 144 may be spaced apart from each other by the second gate dielectric layer 154 therebetween. The first cell transistor CTR1 may include the first channel layer 142, the first gate dielectric layer 152, and the first word line 162. The second cell transistor CTR2 may include the second channel layer 144, the second gate dielectric layer 154, and the second word line 164. In some embodiments, the first channel layer 142, the first gate dielectric layer 152, and the first word line 162 may constitute the first cell transistor CTR1. In some embodiments, the second channel layer 144, the second gate dielectric layer 154, and the second word line 164 may constitute the second cell transistor CTR2. In some embodiments, within one mold opening 130H, the first cell transistor CTR1 and the second cell transistor CTR2 may be arranged to be mirror-image symmetrical with respect to each other (with respect to the first horizontal direction (e.g., X direction)).

Within one mold opening 130H, a first dielectric layer 182 may be disposed between the channel layers 140 and the gate dielectric layers 150 facing each other, and a dielectric liner 184 and a second dielectric layer 186 may be disposed between the word lines WL facing each other. For example, the first and second channel layers 142 and 144 may be spaced apart from each other in the first horizontal direction (X direction) by the first dielectric layer 182 therebetween. The first and second gate dielectric layers 152 and 154 may be spaced apart from each other in the first horizontal direction (X direction) by the first dielectric layer 182 therebetween. The first and second word lines 162 and 164 may be spaced apart from each other in the first horizontal direction (X direction) by the dielectric liner 184 and the second dielectric layer 186 therebetween. According to some embodiments, the first dielectric layer 182 may include silicon oxide, the dielectric liner 184 may include silicon nitride, and the second dielectric layer 186 may include silicon oxide. However, the inventive concept is not limited thereto.

A plurality of contact structures BC may be arranged on the mold layer 130 and in contact with the horizontal portion 140B and the second vertical portion 140C of the channel layer 140. At least a portion of the lower surface (e.g., the bottom surface) of one contact structure BC may be disposed to contact the upper surface (e.g., the top surface) of the horizontal portion 140B of the channel layer 140, and at least a portion of the sidewall of the contact structure BC may be disposed to contact the sidewall of the second vertical portion 140C of the channel layer 140. According to some embodiments, the plurality of contact structures BC may each include a contact pattern 170 in the lower portion of the plurality of contact structures BC and a barrier metal pattern 172 in the upper portion of the plurality of contact structures BC. Here, the contact structure BC may be referred to as a buried contact.

A dielectric spacer 180 including a plurality of spacer layers 180A, 180B, and 180A arranged side-by-side in the first horizontal direction (X direction) may be disposed in an area between the plurality of contact structures BC facing each other. For example, the dielectric spacer 180 may include a pair of first spacer layers 180A spaced apart from each other in the first horizontal direction (X direction) and a second spacer layer 180B therebetween. The dielectric spacer 180 may be between a pair of contact structures BC (e.g., adjacent ones of the plurality of contact structures BC) in the first horizontal direction (X direction)). The second spacer layer 180B may be spaced apart from (the sidewall of) the contact structure BC by the first spacer layer 180A and the second vertical portion 140C of the channel layer 140.

In the semiconductor device 100 according to the inventive concept, the vertical level of the lower surface (e.g., the lowermost surface) of a first spacer layer 180A, which contacts the sidewall of the contact structure BC, from among the plurality of spacer layers 180A, 180B, and 180A, may be higher than the vertical level of the lower surface (e.g., the lowermost surface) of a second spacer layer 180B, which does not contact the sidewall of the contact structure BC. Also, the lower surface (e.g., the lowermost surface) of the first spacer layer 180A may be disposed to contact the upper surface (e.g., the uppermost surface) of the second vertical portion 140C of the channel layer 140, and at least a portion of the sidewall of the second spacer layer 180B may be disposed to contact the sidewall of the second vertical portion 140C of the channel layer 140.

In the semiconductor device 100 according to the inventive concept, the material in (of) the first spacer layer 180A may be different from the material in (of) the second spacer layer 180B. According to some embodiments, a third mold dielectric layer 136, which is the uppermost layer from among the first to third mold dielectric layers 132, 134, and 136 of (constituting) the mold layer 130, may include the same material as the first spacer layer 180A.

An etch stop layer 188 may be disposed on the contact structure BC and the dielectric spacer 180. The etch stop layer 188 may include a plurality of openings 188H, and the upper surfaces (e.g., the top surfaces) of the plurality of contact structures BC may be exposed through the plurality of openings 188H.

A capacitor structure 190 may be disposed on the etch stop layer 188. The capacitor structure 190 may include a lower electrode 192, a capacitor dielectric layer 194, and an upper electrode 196. The sidewall of the lower portion (e.g., the bottom portion) of the lower electrode 192 may be disposed within an opening 188H of the etch stop layer 188, and the lower electrode 192 may extend in the vertical direction (Z direction). The capacitor dielectric layer 194 may be disposed on the sidewall of the lower electrode 192, and the upper electrode 196 may be on (e.g., cover or overlap) the capacitor dielectric layer 194 on the lower electrode 192.

To meet performance needs and economic feasibility, it may be needed to increase the degree of integration of semiconductor devices. In particular, the degree of integration of memory devices may be an important factor in determining the economic feasibility of a product. Since the degree of integration of a two (2)-dimensional memory device may be mainly affected by the area occupied by a unit memory cell, it may be influenced by the level of micro-pattern formation technology. However, expensive equipment may be needed to form fine patterns and the area of a chip die is limited. Therefore, although the degree of integration of 2-dimensional memory devices is increasing, it may still be limited. Therefore, semiconductor devices including vertical channel transistors (VCTs) has been developed.

Generally, in a semiconductor device including VCTs, as the degree of integration of the semiconductor device increases, the size of cell transistors may also be reduced, and thus the contact area between a buried contact and a vertical channel layer may decrease. The decrease in the contact area may result in an increase in the contact resistance, thereby causing deterioration of electrical characteristics of the semiconductor device.

/In the semiconductor device 100 according to the inventive concept, the channel layer 140 may be formed to contact both the lower surface (e.g., the bottom surface) and the sidewall of the contact structure BC by surrounding any one of lower corners (e.g., bottom corners) of the contact structure BC serving as a buried contact of the semiconductor device 100 including the VCT (structure), thereby increasing the contact area between the contact structure BC and the channel layer 140.

The semiconductor device 100 according to the inventive concept may reduce the contact resistance by increasing the contact area between the contact structure BC and the channel layer 140, thereby enhancing the electrical characteristics to improve the product reliability.

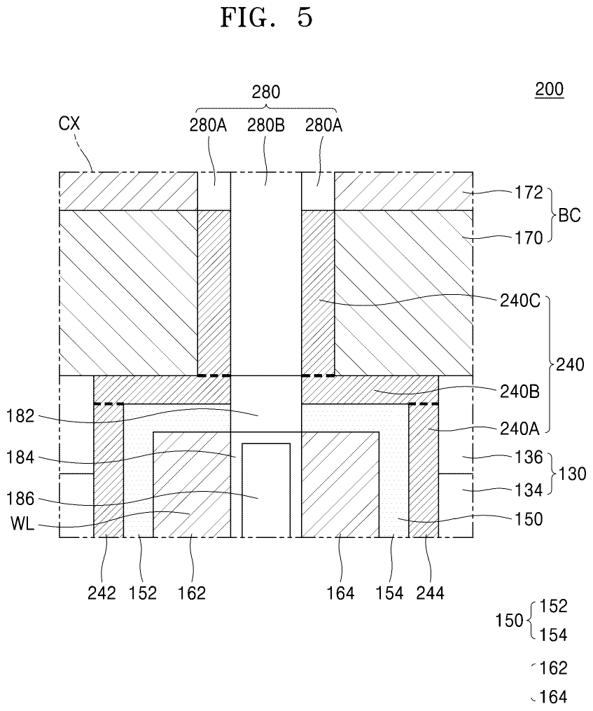

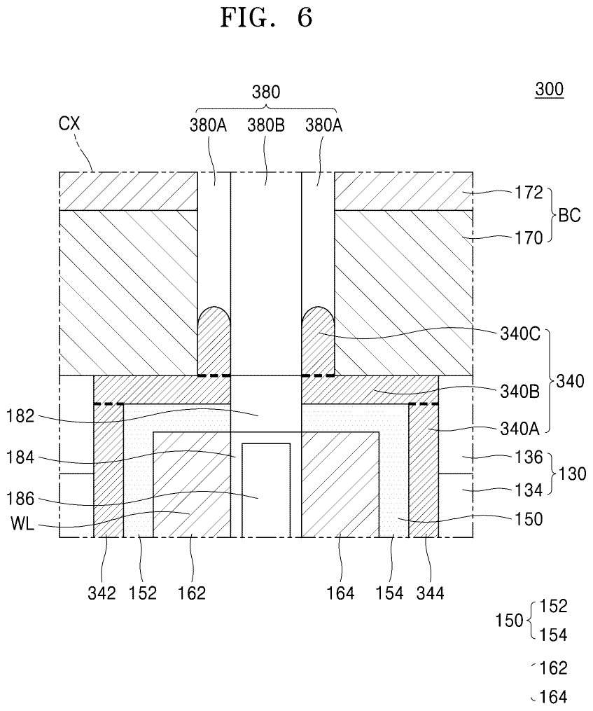

FIGS. 5 and 6 are cross-sectional views showing semiconductor devices according to some embodiments.

Most of components of semiconductor device 200 in FIG. 5 and semiconductor device 300 in FIG. 6 described below and materials in the components of the semiconductor devices 200 and 300 are (substantially) the same as or similar to those described with reference to FIGS. 1 to 4 above. Therefore, for convenience of explanation, descriptions below focus on the differences from the semiconductor device 100 described above.

Referring to FIG. 5, the semiconductor device 200 may include the bit line BL, the word line WL, a channel layer 240, the gate dielectric layer 150, and the contact structure BC.

In the semiconductor device 200 according to some embodiments, a plurality of channel layers 240 may each include a first vertical portion 240A, a horizontal portion 240B on the first vertical portion 240A, and a second vertical portion 240C on the horizontal portion 240B. The first vertical portion 240A may be disposed downward from one end of the horizontal portion 240B (e.g., a first end of the horizontal portion 240B in the first horizontal direction (X direction)), and the second vertical portion 240C may be disposed upward from the other end of the horizontal portion 240B (e.g., a second end of the horizontal portion 240B opposite to the first end of the horizontal portion 240B in the first horizontal direction (X direction)). In other words, the first vertical portion 240A and the second vertical portion 240C may be arranged to not to overlap each other in the vertical direction (Z direction). The first vertical portion 240A, the second vertical portion 240C, and the horizontal portion 240B may form a unitary structure.

A plurality of contact structures BC may be arranged on the mold layer 130 and in contact with the horizontal portion 240B and the second vertical portion 240C of the channel layer 240. According to some embodiments, the plurality of contact structures BC may each include the contact pattern 170 in the lower portion and the barrier metal pattern 172 in the upper portion.

In the semiconductor device 200 according to some embodiments, at least a portion of the lower surface (e.g., the bottom surface) of one contact structure BC may be disposed to contact the upper surface (e.g., the top surface) of the horizontal portion 240B of the channel layer 240, and the entire sidewall of the contact pattern 170 of the contact structure BC may be disposed to contact the sidewall of the second vertical portion 240C of the channel layer 240. In other words, the vertical level of the upper surface (e.g., the top surface) of the channel layer 240 may be (substantially) equal to the vertical level of the upper surface (e.g., the top surface) of the contact pattern 170. For example, the upper surface of the channel layer 240 (e.g., the upper surface of the second vertical portion 240C) may be coplanar with the upper surface of the contact pattern 170.

A dielectric spacer 280 including a plurality of spacer layers 280A, 280B, and 280A arranged side-by-side in the first horizontal direction (X direction) may be disposed in an area between the plurality of contact structures BC facing each other. For example, the dielectric spacer 280 may include a pair of first spacer layers 280A spaced apart from each other in the first horizontal direction (X direction) and a second spacer layer 280B therebetween. The dielectric spacer 280 may be between a pair of contact structures BC (e.g., adjacent ones of the plurality of contact structures BC) in the first horizontal direction (X direction)). The second spacer layer 280B may be spaced apart from (the sidewall of) the contact structure BC by the first spacer layer 280A and the second vertical portion 240C of the channel layer 240.

In detail, from among the plurality of spacer layers 280A, 280B, and 280A, the vertical level of the lower surface (e.g., the lowermost) surface of the first spacer layer 280A, which contacts the sidewall of the contact structure BC, may be higher than the vertical level of the lower surface (e.g., the lowermost surface) of a second spacer layer 280B, which does not contact the sidewall of the contact structure BC.

In the semiconductor device 200 according to some embodiments, the vertical level of the lower surface (e.g., the lowermost surface) of the first spacer layer 280A may be (substantially) equal to the vertical level of the upper surface (e.g., the uppermost surface) of the contact pattern 170. Also, the lower surface (e.g., the lowermost surface) of the first spacer layer 280A may be disposed to contact the upper surface (e.g., the uppermost surface) of the second vertical portion 240C of the channel layer 240, and at least a portion of the sidewall of the second spacer layer 280B may be disposed to contact the sidewall of the second vertical portion 240C of the channel layer 240. The material in (e.g., constituting) the first spacer layer 280A may be different from the material in (of) the second spacer layer 280B.

Referring to FIG. 6, a semiconductor device 300 may include the bit line BL, the word line WL, a channel layer 340, the gate dielectric layer 150, and the contact structure BC.

In the semiconductor device 300 according to some embodiments, a plurality of channel layers 340 may each include a first vertical portion 340A, a horizontal portion 340B on the first vertical portion 340A, and a second vertical portion 340C on the horizontal portion 340B. The first vertical portion 340A may be disposed downward from one end of the horizontal portion 340B (e.g., a first end of the horizontal portion 340B in the first horizontal direction (X direction)), and the second vertical portion 340C may be disposed upward from the other end of the horizontal portion 340B (e.g., a second end of the horizontal portion 340B opposite to the first end of the horizontal portion 340B in the first horizontal direction (X direction)). In other words, the first vertical portion 340A and the second vertical portion 340C may be arranged to not overlap each other in the vertical direction (Z direction). The first vertical portion 340A, the second vertical portion 340C, and the horizontal portion 340B may form an unitary structure.

A plurality of contact structures BC may be arranged on the mold layer 130 and in contact with the horizontal portion 340B and the second vertical portion 340C of the channel layer 340. According to some embodiments, the plurality of contact structures BC may each include the contact pattern 170 in the lower portion and the barrier metal pattern 172 in the upper portion.

In the semiconductor device 300 according to some embodiments, at least a portion of the lower surface (e.g., the bottom surface) of one contact structure BC may be disposed to contact the upper surface (e.g., the top surface) of the horizontal portion 340B of the channel layer 340, and at least a portion of the sidewall of the contact structure BC may be disposed to contact the sidewall of the second vertical portion 340C of the channel layer 340. Here, the second vertical portion 340C may have a rounded upper surface (e.g., a rounded top surface). For example, an upper end (e.g., a top end) of the second vertical portion 340C may be convex toward a dielectric spacer 380 (e.g., a first spacer layer 380A).

The dielectric spacer 380 including a plurality of spacer layers 380A, 380B, and 380A arranged side-by-side in the first horizontal direction (X direction) may be disposed in an area between the plurality of contact structures BC facing each other. For example, the dielectric spacer 380 may include a pair of the first spacer layers 380A spaced apart from each other in the first horizontal direction (X direction) and a second spacer layer 380B therebetween. The dielectric spacer 380 may be between a pair of contact structures BC (e.g., adjacent ones of the plurality of contact structures BC) in the first horizontal direction (X direction)). The second spacer layer 380B may be spaced apart from (the sidewall of) the contact structure BC by the first spacer layer 380A and the second vertical portion 340C of the channel layer 340.

In detail, from among the plurality of spacer layers 380A, 380B, and 380A, the vertical level of the lower surface (e.g., the lowermost surface) of the first spacer layer 380A, which contacts the sidewall of the contact structure BC, may be higher than the vertical level of the lower surface (e.g., the lowermost surface) of the second spacer layer 380B, which does not contact the sidewall of the contact structure BC.

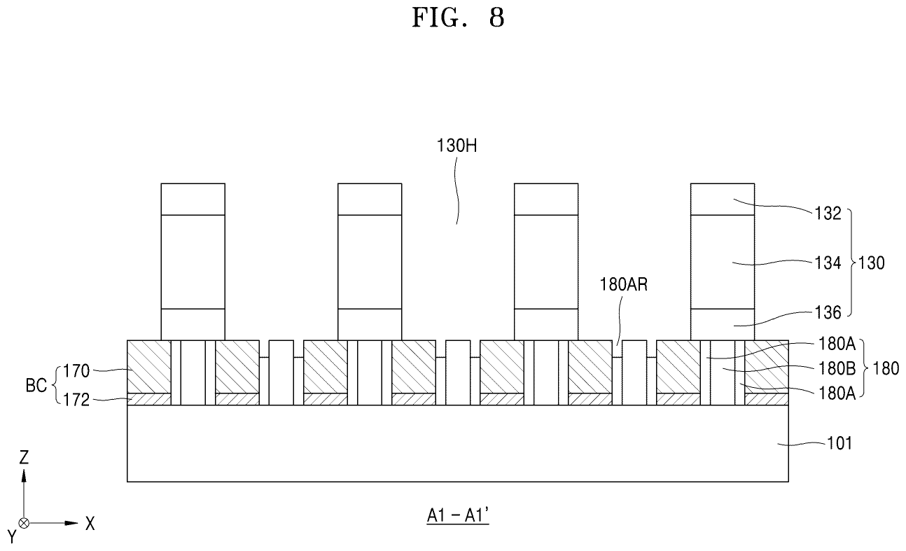

In the semiconductor device 300 according to some embodiments, the first spacer layer 380A may have a rounded lower surface (e.g., a rounded bottom surface) in a shape corresponding to that of the rounded upper surface (e.g., the rounded top surface) of the second vertical portion 340C. For example, the lower surface of the first spacer layer 380A may be concave toward the upper surface of the first spacer layer 380A. As described below, this shape may be a characteristic due to formation of a first recessed area 180AR (refer to FIG. 8) in the first spacer layer 380A through a wet etching process. Also, at least a portion of the sidewall of the second spacer layer 380B may be disposed to contact the sidewall of the second vertical portion 340C of the channel layer 340. The material in (of) the first spacer layer 380A may be different from the material in (of) the second spacer layer 380B.

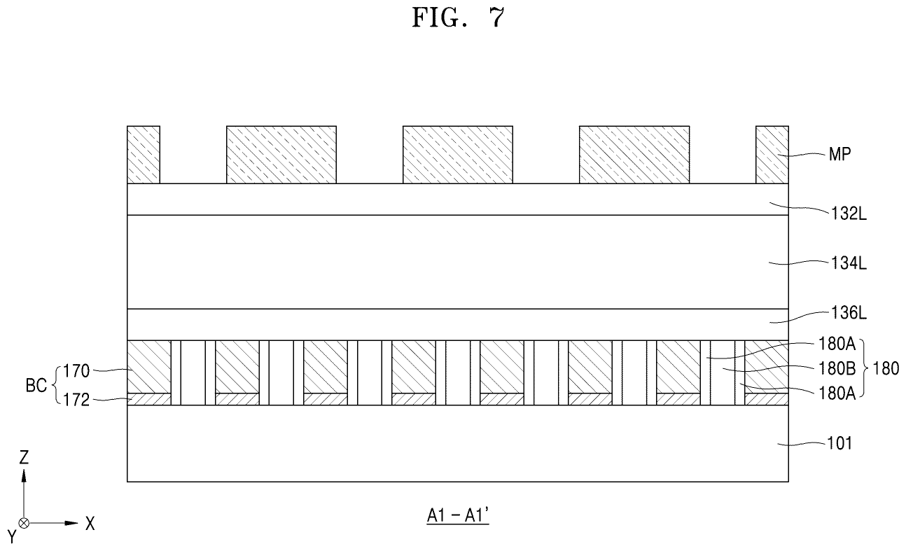

FIGS. 7 to 22 are cross-sectional views showing, in a process sequence, a method of manufacturing a semiconductor device, according to some embodiments.

Referring to FIG. 7, on a first substrate 101, the plurality of contact structures BC may be formed, and the dielectric spacer 180 may be formed in the area between (adjacent ones of) the plurality of contact structures BC.

The first substrate 101 may be a wafer, including silicon (Si). In some embodiments, the first substrate 101 may include a wafer, including a semiconductor element, such as germanium (Ge) and/or a compound semiconductor, such as silicon carbide (SiC), gallium arsenide (GaAs), indium arsenide (InAs), and/or indium phosphide (InP). In some embodiments, the first substrate 101 may have a silicon-on-insulator (SOI) structure.

The plurality of contact structures BC may each include the contact pattern 170 in the upper portion and the barrier metal pattern 172 in the lower portion. The contact pattern 170 may include a metal (e.g., tungsten, titanium, and tantalum), and the barrier metal pattern 172 may include a conductive metal nitride (e.g., titanium nitride and tantalum nitride). However, the inventive concept is not limited thereto.

The dielectric spacer 180 including the plurality of spacer layers 180A, 180B, and 180A arranged side-by-side in the first horizontal direction (X direction) may be formed in an area between (adjacent ones of) the plurality of contact structures BC facing each other (in the first direction (X direction)). The material in (of) the first spacer layer 180A may be different from the material in (of) the second spacer layer 180B.

Next, first, second, and third mold forming layers 132L, 134L, and 136L may be formed on the plurality of contact structures BC and the dielectric spacer 180. According to some embodiments, the first, second, and third mold forming layers 132L, 134L, and 136L may include different dielectric materials. In some embodiments, the first mold forming layer 132L and the third mold forming layer 136L may include the same material, and the second mold forming layer 134L may include a material different from (that constituting) the first mold forming layer 132L and the third mold forming layer 136L.

According to some embodiments, the third mold forming layer 136L, which is the lower layer (e.g., the bottommost layer) from among the first, second, and third mold forming layers 132L, 134L, and 136L, may be formed to include the same material as the first spacer layer 180A. The second mold forming layer 134L may be between the first mold forming layer 132L, and the third mold forming layer 136L in the vertical direction (Z direction).

Next, a mask pattern MP may be formed on the first mold forming layer 132L. The mask pattern MP may be formed to have a pattern that exposes portions of the first, second, and third mold forming layers 132L, 134L, and 136L corresponding to a plurality of mold openings 130H (refer to FIG. 8).

Referring to FIG. 8, an etching process may be performed on the first, second, and third mold forming layers 132L, 134L, and 136L (refer to FIG. 7) by using the mask pattern MP (refer to FIG. 7) as an etching mask.

The etching process may include (e.g., may be) a dry etching process. The mold layer 130 including the first, second, and third mold dielectric layers 132, 134, and 136 and having the plurality of mold openings 130H may be formed.

According to some embodiments, through the dry etching process, an exposed upper portion of the first spacer layer 180A in the dielectric spacer 180 may be etched together, and thus the first recessed area 180AR may be formed. In other words, the first, second, and third mold forming layers 132L, 134L, and 136L (refer to FIG. 7) and the first spacer layer 180A may be etched together through a single etching process.

According to some embodiments, an additional etching process may be performed to etch the exposed upper portion of the first spacer layer 180A in the dielectric spacer 180. The additional etching process may be a wet etching process. For example, the first mold forming layer 132L and the second mold forming layer 134L (refer to FIG. 7) may be etched first through the dry etching process, and the third mold forming layer 136L (refer to FIG. 7) and the first spacer layer 180A may be etched later through the wet etching process. Therefore, the first recessed area 180AR may be formed. The etching processes may not be limited to the above-mentioned embodiments.

Next, the mask pattern MP (refer to FIG. 7) may be removed through ashing and strip processes.

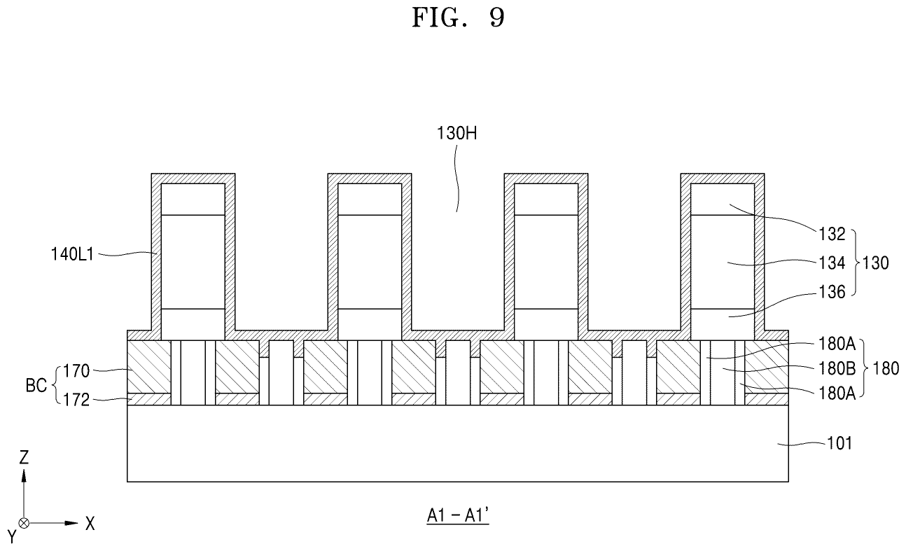

Referring to FIG. 9, a first channel forming layer 140L1 may be formed on the mold layer 130 to (conformally) cover the inner walls of the plurality of mold openings 130H (and the inner walls of the first recessed area 180AR).

According to some embodiments, the first channel forming layer 140L1 may include an oxide semiconductor material. The oxide semiconductor material may include, for example, indium (In). For example, the oxide semiconductor material may include InGaZnOₓ (IGZO), Sn-doped InGaZnOₓ (IGZO), W-doped InGaZnOₓ (IGZO), and/or InZnOₓ (IZO).

According to some embodiments, the first channel forming layer 140L1 may be formed through, for example, a chemical vapor deposition (CVD) process, a low pressure CVD process, a plasma enhanced CVD process, a metal organic CVD (MOCVD) process, and/or an atomic layer deposition process.

According to some embodiments of the inventive concept, the first channel forming layer 140L1 may be formed to fill the first recessed area 180AR (refer to FIG. 8). In other words, the first channel forming layer 140L1 may be formed to contact at least a portion of the upper surface (e.g., the top surface) of the plurality of contact structures BC and at least a portion of the sidewalls of the plurality of contact structures BC.

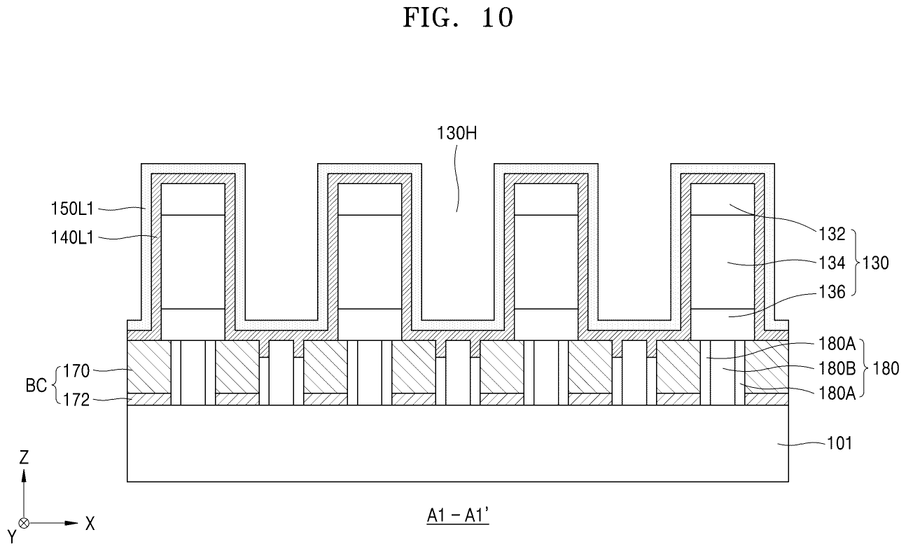

Referring to FIG. 10, a first gate dielectric film forming layer 150L1 may be (conformally) formed on the first channel forming layer 140L1.

The first gate dielectric film forming layer 150L1 may include a high-k material having a higher dielectric constant than silicon oxide.

According to some embodiments, the first gate dielectric film forming layer 150L1 may be formed through, for example, a CVD process, a low pressure CVD process, a plasma enhanced CVD process, an MOCVD process, and/or an atomic layer deposition process.

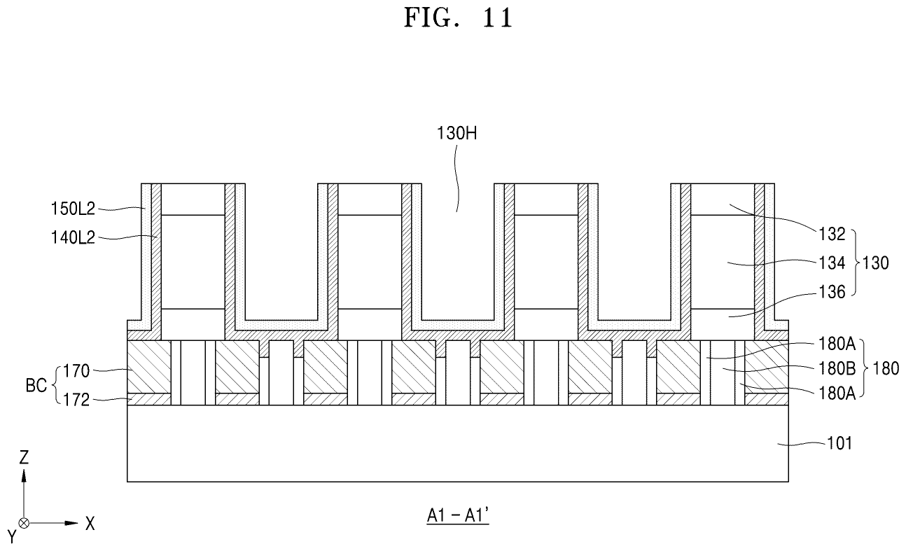

Referring to FIG. 11, the first channel forming layer 140L1 (refer to FIG. 10) and the first gate dielectric film forming layer 150L1 (refer to FIG. 10) may be removed from the upper surface (e.g., the top surface) of the mold layer 130.

The removal process may be an etch-back process or a polishing process. Therefore, a plurality of second channel forming layers 140L2 and a plurality of second gate dielectric film forming layers 150L2 may be formed on the inner walls of the plurality of mold openings 130H.

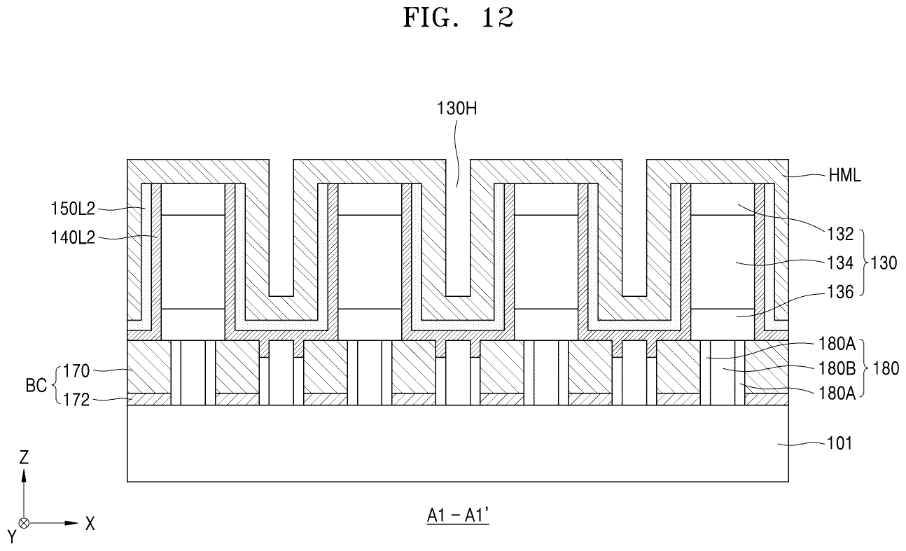

Referring to FIG. 12, a hard mask layer HML may be (conformally) formed on the mold layer 130 and the plurality of second gate dielectric film forming layers 150L2.

According to some embodiments, the hard mask layer HML may include a material with a high etch selectivity with respect to dielectric materials. For example, the hard mask layer HML may include titanium nitride (TiN).

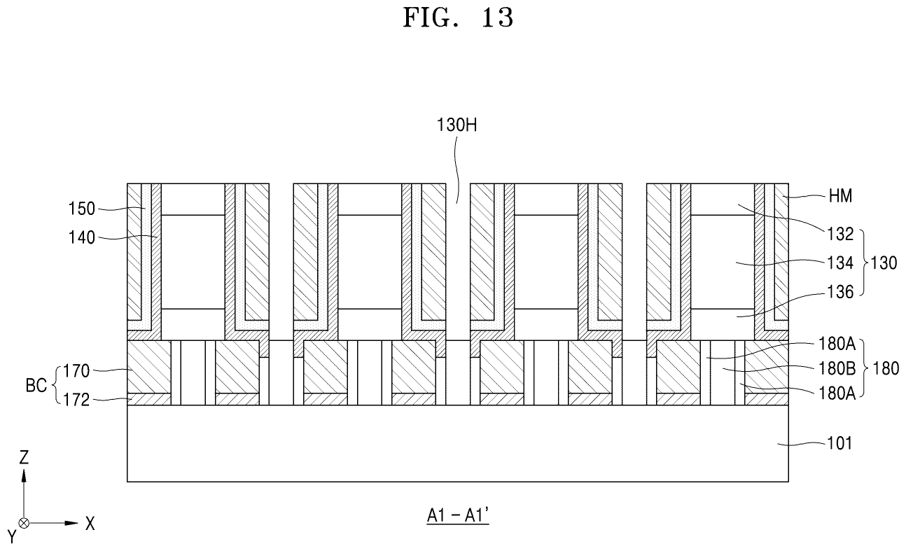

Referring to FIG. 13, (a portion of) the hard mask layer HML (refer to FIG. 12) and (a portion of) the plurality of second channel forming layers 140L2 (refer to FIG. 12), and (a portion of) the second gate dielectric film forming layers 150L2 (refer to FIG. 12) may be removed to expose the upper surface (e.g., the top surface) of the mold layer 130 and (a portion of) the upper surface (e.g., the top surface) of the second spacer layer 180B.

The removal process may be an etch-back process or a full-scale etch process. Therefore, a hard mask HM may be formed on a plurality of gate dielectric layers 150 inside the plurality of mold openings 130H. Also, the upper surface (e.g., the top surface) of the second spacer layer 180B may be exposed inside the plurality of mold openings 130H. In other words, a pair of the channel layers 140 and a pair of the gate dielectric layers 150 may be formed inside one mold opening 130H.

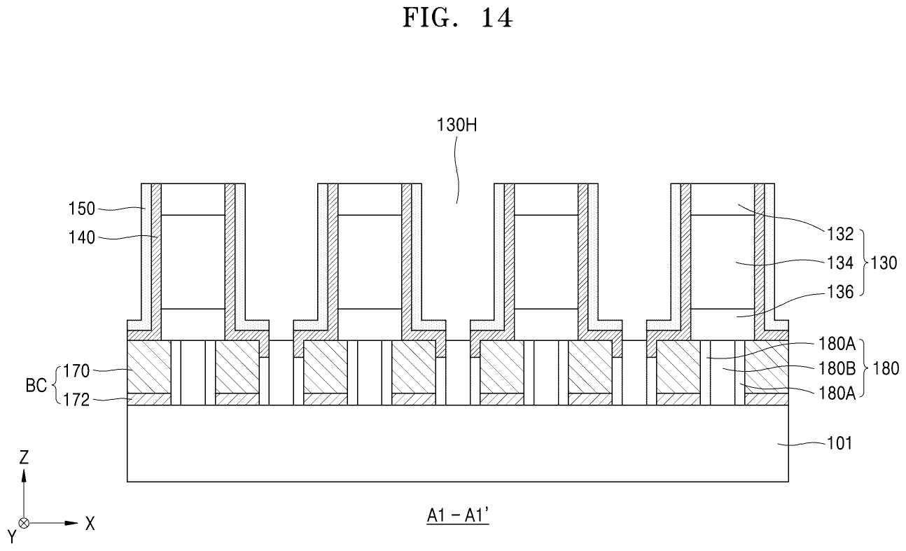

Referring to FIG. 14, after forming the channel layer 140 and the gate dielectric layer 150, the hard mask HM (refer to FIG. 13) may be (completely) removed.

In this way, the hard mask HM (refer to FIG. 13) is (completely) removed before a subsequent manufacturing process, thereby preventing defects due to residue of the hard mask HM (refer to FIG. 13) in the subsequent manufacturing process.

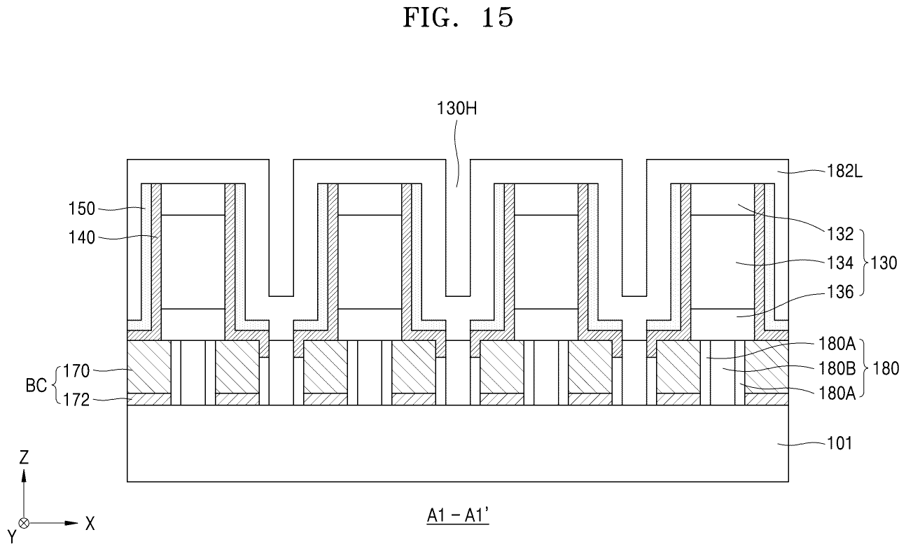

Referring to FIG. 15, a first dielectric forming layer 182L may be (conformally) formed on the mold layer 130 and the gate dielectric layer 150 (and the channel layer 140).

The first dielectric forming layer 182L may include, for example, silicon oxide. According to some embodiments, the first dielectric forming layer 182L may be formed through a CVD process, a low pressure CVD process, a plasma enhanced CVD process, an MOCVD process, and/or an atomic layer deposition process.

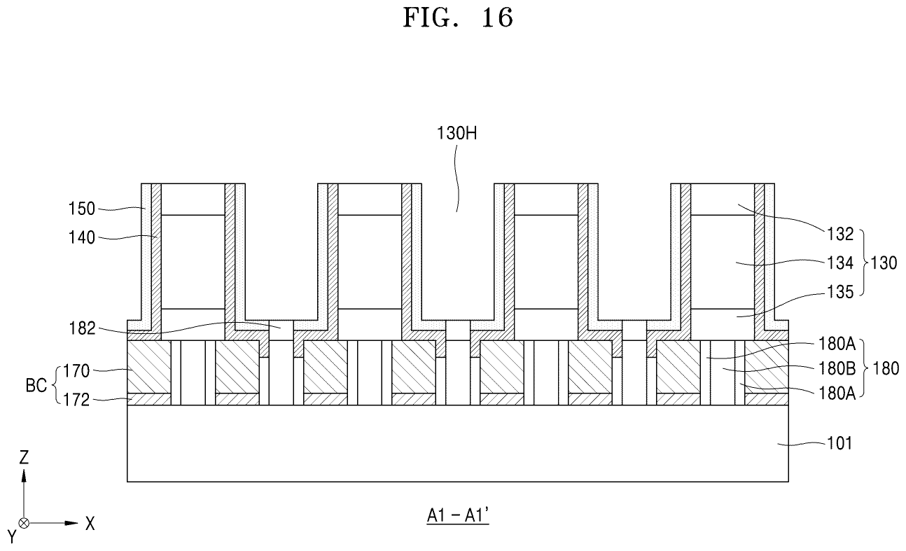

Referring to FIG. 16, the first dielectric layer 182 may be formed by performing an etch-back process on the first dielectric forming layer 182L.

Therefore, the first dielectric layer 182 may be formed between a pair of the channel layers 140 in the first horizontal direction (X direction) and between a pair of the gate dielectric layer 150 in the first horizontal direction (X direction) inside each of the plurality of mold openings 130H.

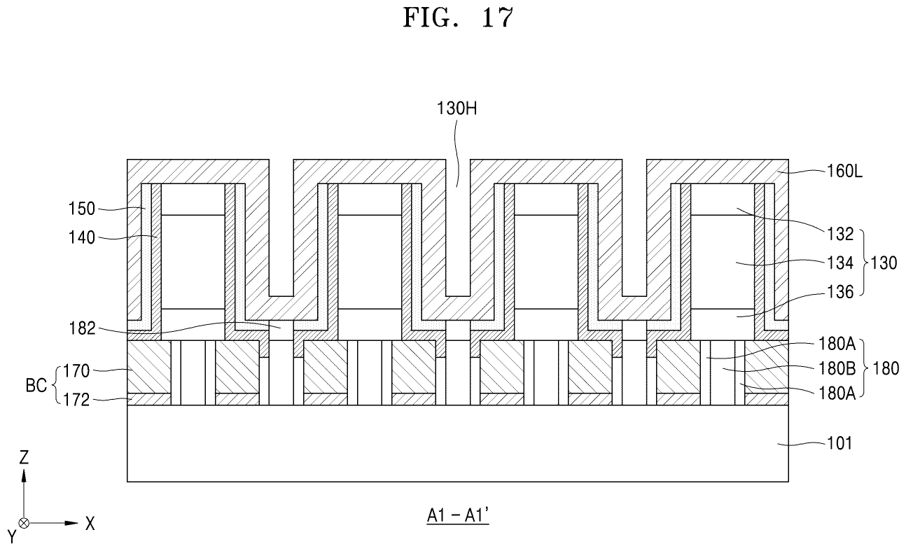

Referring to FIG. 17, a gate electrode layer 160L may be (conformally) formed on the mold layer 130, the gate dielectric layer 150, and the first dielectric layer 182 (and the channel layer 140).

According to some embodiments, the gate electrode layer 160L may include Ti, TiN, Ta, TaN, W, WN, TiSiN, WSiN, polysilicon, and/or a combination thereof.

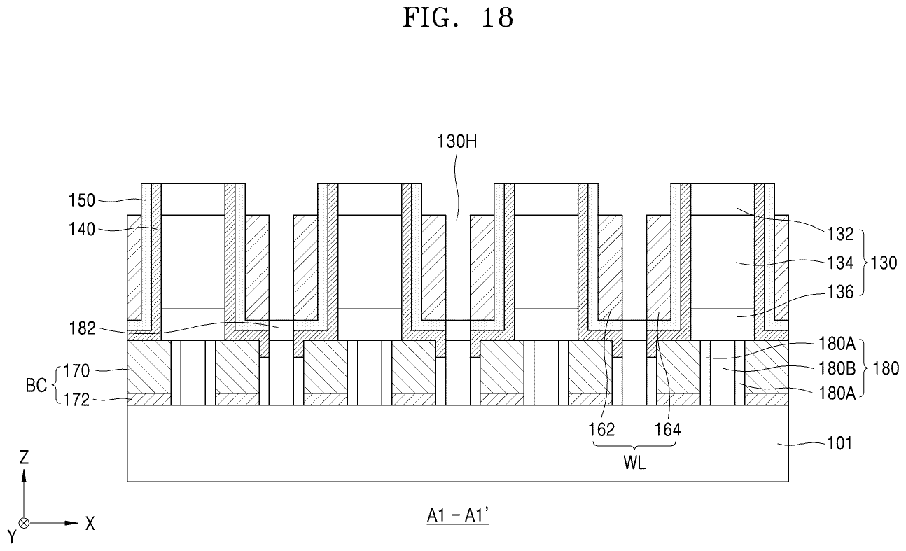

Referring to FIG. 18, an anisotropic etching process may be performed on the gate electrode layer 160L (refer to FIG. 17), thereby forming the word lines WL (the first and second word lines 162 and 164) on the (inner) lower surface and the (inner) sidewalls of the gate dielectric layer 150 inside each of the plurality of mold openings 130H.

A portion of the gate electrode layer 160L (refer to FIG. 17) disposed on the sidewalls of the upper portion of the mold layer 130 may be removed through the anisotropic etching process.

Therefore, by the anisotropic etching process, the gate electrode layer 160L (refer to FIG. 17), a pair of the first word line 162 and the second word line 164 may be formed inside one mold opening 130H.

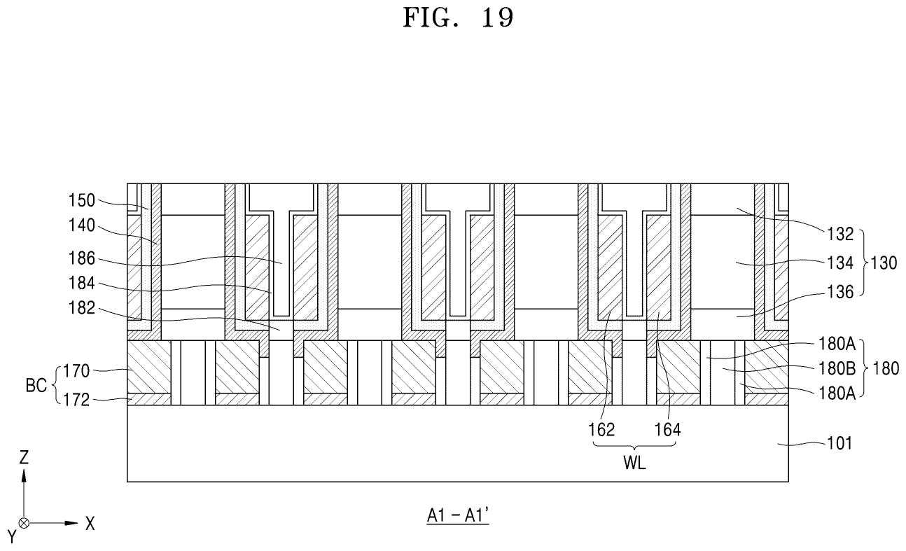

Referring to FIG. 19, the dielectric liner 184 and the second dielectric layer 186 may be formed inside each of the plurality of mold openings 130H (refer to FIG. 18).

The dielectric liner 184 and the second dielectric layer 186 may be formed between a pair of the first word line 162 and the second word line 164 (in the first direction (X direction)), and the dielectric liner 184 may be formed on a portion of the sidewalls of the gate dielectric layer 150.

In detail, portions of the dielectric liner 184 and the second dielectric layer 186 disposed on the upper surface (e.g., the top surface) of the mold layer 130 may be removed through an etch-back process or a planarization process, thereby leaving the dielectric liner 184 and the second dielectric layer 186 only inside each of the plurality of mold openings 130H (refer to FIG. 18).

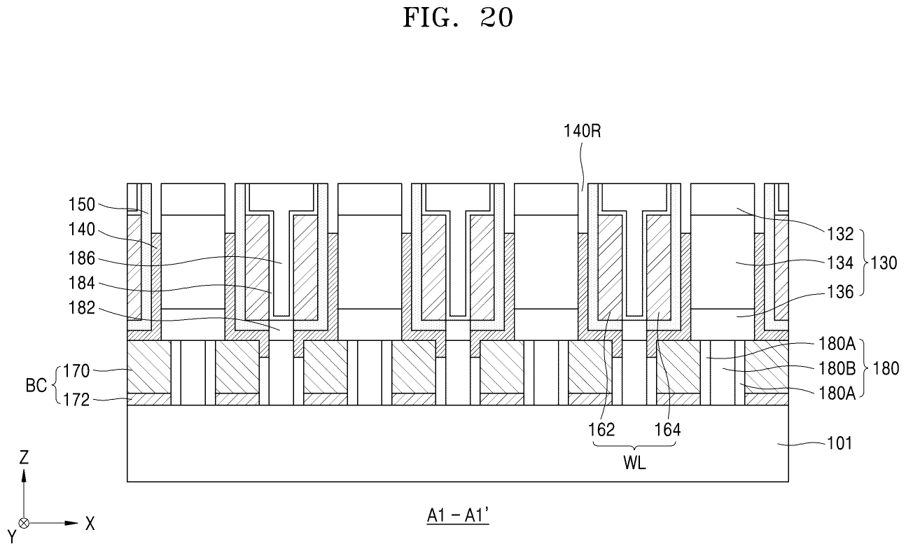

Referring to FIG. 20, the upper portions of the plurality of channel layers 140 may be etched to form a second recessed area 140R.

By selectively etching only the plurality of channel layers 140, the second recessed area 140R may be formed to expose a portion of the sidewall of the mold layer 130 and a portion of the sidewall of the gate dielectric layer 150.

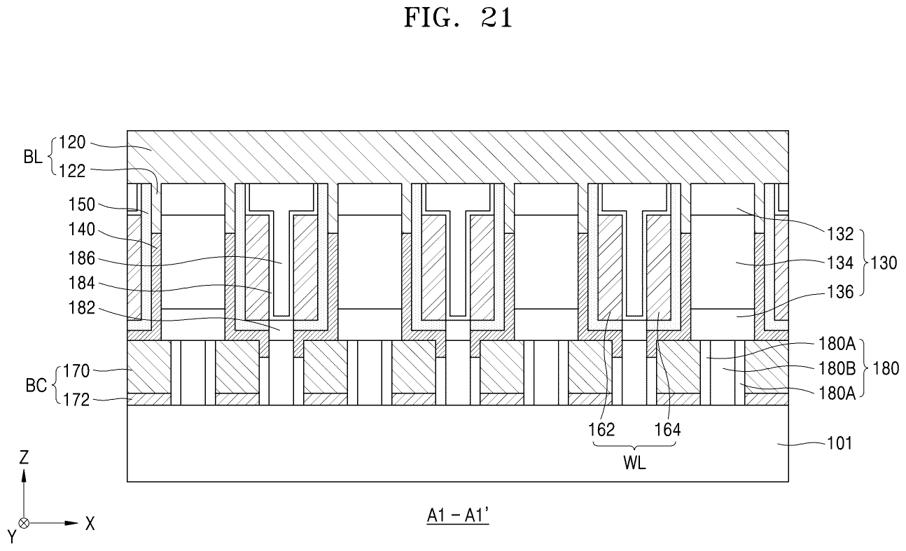

Referring to FIG. 21, the bit line BL that fills the second recessed area 140R (refer to FIG. 20) and extends in the first horizontal direction (X direction) may be formed.

The bit line BL may include the horizontal extension 120 and the plurality of vertical protrusions 122 protruding downward from the horizontal extension 120. Here, the plurality of vertical protrusions 122 may be formed (may be the characteristic) due to the second recessed area 140R (refer to FIG. 20).

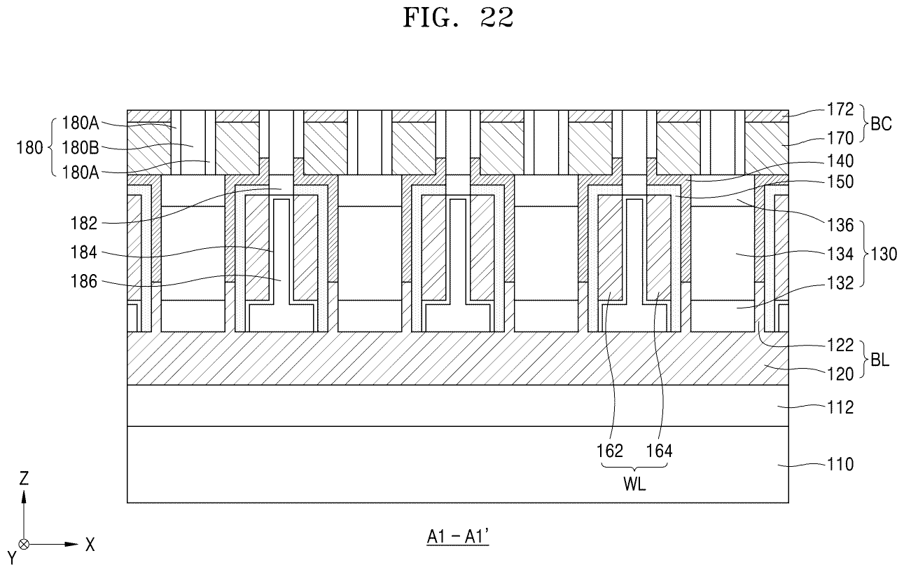

Referring to FIG. 22, the first substrate 101 on which the bit lines BL are formed may be turned over and aligned with the substrate 110.

According to some embodiments, the bit lines BL formed on the first substrate 101 and the upper surface (e.g., the top surface) of the lower dielectric layer 112 formed on the substrate 110 may be bonded to each other. According to some embodiments, the lower dielectric layer 112 may be formed on (the lower surface of) the bit lines BL first, and then the lower dielectric layer 112 and the upper surface (e.g., the top surface) of the substrate 110 may be bonded to each other.

Referring back to FIG. 3, the capacitor structure 190 may be formed on the contact structure BC. In detail, the capacitor structure 190 may be formed to include the lower electrode 192, the capacitor dielectric layer 194, and the upper electrode 196. The sidewall of the lower portion (e.g., the bottom portion) of the lower electrode 192 may be disposed within an opening 188H of the etch stop layer 188, and the lower electrode 192 may extend in the vertical direction (Z direction). The capacitor dielectric layer 194 may be disposed on the sidewall of the lower electrode 192, and the upper electrode 196 may be on (e.g., cover or overlap) the capacitor dielectric layer 194 on the lower electrode 192.

Through the method, the semiconductor device 100 according to the inventive concept may be manufactured.

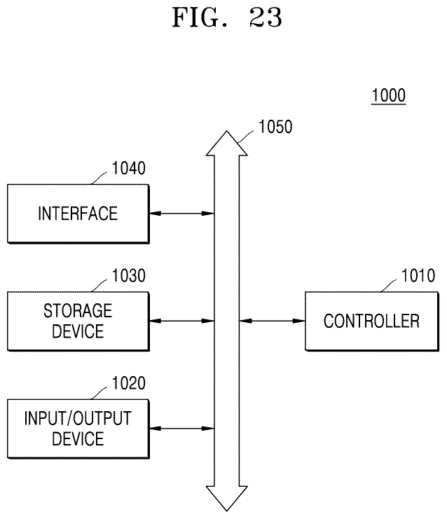

FIG. 23 is a configuration diagram showing a system including a semiconductor device according to some embodiments.

Referring to FIG. 23, a system 1000 may include a controller 1010, an input/output device 1020, a storage device 1030, an interface 1040, and a bus 1050.

The system 1000 may be a mobile system or a system that transmits or receives information. According to some embodiments, the mobile system may be a portable computer, a web tablet, a mobile phone, a digital music player, or a memory card.

The controller 1010 may be for controlling a program executed by the system 1000 and may include a microprocessor, a digital signal processor, a microcontroller, or the like.

The input/output device 1020 may be used to input or output data to or from the system 1000. The system 1000 may be (electrically) connected to an external device, e.g., a personal computer or a network, and exchange data with the external device by using the input/output device 1020. The input/output device 1020 may be, for example, a touch screen, a touch pad, a keyboard, or a display device. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The storage device 1030 may store data for operation of the controller 1010 or data processed by the controller 1010. The storage device 1030 may include any one of the semiconductor devices 100, 200, and 300 according to the inventive concept described above.

The interface 1040 may be a data transmission path between the system 1000 and an external device. The controller 1010, the input/output device 1020, the storage device 1030, and the interface 1040 may communicate with one another via the bus 1050.

While the inventive concept has been particularly shown and described with reference to embodiments thereof, it will be understood that various changes in form and details may be made therein without departing from the scope of the following claims.

What is claimed is:

1. A semiconductor device comprising:
a substrate;
a bit line extending in a first horizontal direction on the substrate;
a channel layer on the bit line, wherein the channel layer includes an oxide semiconductor material that includes indium (In), and wherein the channel layer includes a first vertical portion, a horizontal portion on the first vertical portion, and a second vertical portion on the horizontal portion;
a gate dielectric layer in contact with a first sidewall of the first vertical portion of the channel layer and a lower surface of the horizontal portion of the channel layer;
a word line on an inner sidewall and a lower surface of the gate dielectric layer, wherein the word line extends in a second horizontal direction that intersects with the first horizontal direction;
contact structures, wherein at least one of the contact structures is in contact with the horizontal portion and the second vertical portion of the channel layer; and
a capacitor structure on the at least one of the contact structures,
wherein the first horizontal direction and the second horizontal direction are parallel with an upper surface of the substrate.

2. The semiconductor device of claim 1, wherein the first vertical portion is at a first end of the horizontal portion in the first horizontal direction, and the second vertical portion is at a second end of the horizontal portion opposite to the first end in the first horizontal direction, and,
wherein the first vertical portion and the second vertical portion do not overlap each other in a vertical direction that is perpendicular to the upper surface of the substrate.

3. The semiconductor device of claim 2, wherein at least a portion of a lower surface of the at least one of the contact structures is in contact with an upper surface of the horizontal portion of the channel layer, and at least a portion of a sidewall of the at least one of the contact structures is in contact with a sidewall of the second vertical portion of the channel layer.

4. The semiconductor device of claim 2, wherein an upper surface of the second vertical portion of the channel layer has a rounded shape.

5. The semiconductor device of claim 1, further comprising:
a dielectric spacer including a plurality of spacer layers that are arranged in the first horizontal direction, wherein the plurality of spacer layers is between ones of contact structures facing each other in the first horizontal direction,
wherein the plurality of spacer layers includes a first spacer layer and a second spacer layer,
wherein a lower surface of the first spacer layer is farther than a lower surface of the second spacer layer from the upper surface of the substrate,
wherein the second spacer layer is spaced apart from the contact structures by the first spacer layer and the second vertical portion of the channel layer.

6. The semiconductor device of claim 5, wherein the lower surface of the first spacer layer is in contact with an upper surface of the second vertical portion of the channel layer, and wherein at least a portion of a sidewall of the second spacer layer is in contact with a sidewall of the second vertical portion of the channel layer.

7. The semiconductor device of claim 5, further comprising:
a mold layer that is in contact with a second sidewall of the first vertical portion of the channel layer and a sidewall of the horizontal portion of the channel layer,
wherein the second vertical portion of the channel layer is farther than an upper surface of the mold layer from the upper surface of the substrate, and
wherein the second sidewall of the first vertical portion of the channel layer is opposite to the first sidewall of the first vertical portion of the channel layer in the first horizontal direction.

8. The semiconductor device of claim 7, wherein the mold layer includes a plurality of mold dielectric layers stacked in a vertical direction that is perpendicular to the upper surface of the substrate, and
wherein an uppermost mold dielectric layer from among the plurality of mold dielectric layers and the first spacer layer include a same material.

9. The semiconductor device of claim 7, wherein the bit line includes a horizontal extension and a vertical protrusion protruding from the horizontal extension in a vertical direction that is perpendicular to the upper surface of the substrate, and
wherein an upper surface of the vertical protrusion of the bit line is in contact with a lower surface of the first vertical portion of the channel layer.

10. The semiconductor device of claim 9, wherein a first sidewall of the vertical protrusion of the bit line is in contact with a sidewall of the mold layer,
wherein a second sidewall of the vertical protrusion of the bit line is in contact with an outer sidewall of the gate dielectric layer, and
wherein the second sidewall of the vertical protrusion of the bit line is opposite to the first sidewall of the vertical protrusion of the bit line.

11. A semiconductor device comprising:
a substrate;
a bit line extending in a first horizontal direction on the substrate;
a mold layer on the bit line, wherein the mold layer includes a mold opening;
a channel layer in the mold opening, wherein the channel layer includes a horizontal portion, a first vertical portion below a first end of the horizontal portion, and a second vertical portion above a second end of the horizontal portion that is opposite to the first end of the horizontal portion in the first horizontal direction, and wherein the channel layer includes IGZO (InGaZnOₓ);
a gate dielectric layer below the channel layer in the mold opening, wherein the gate dielectric layer includes a high-k material;
a word line below the gate dielectric layer in the mold opening, wherein the word line extends in a second horizontal direction that intersects with the first horizontal direction;
a contact structure in contact with an upper surface of the mold layer, an upper surface of the horizontal portion of the channel layer, and an outer sidewall of the second vertical portion of the channel layer; and
a capacitor structure on the contact structure,
wherein the first horizontal direction and the second horizontal direction are parallel with an upper surface of the substrate.

12. The semiconductor device of claim 11, wherein inner sidewalls of the second vertical portion of the channel layer that are spaced apart from the contact structure and inner sidewalls of the word line that are spaced apart from the gate dielectric layer are aligned with each other in a vertical direction that is perpendicular to the upper surface of the substrate.

13. The semiconductor device of claim 12, wherein the first vertical portion and the horizontal portion of the channel layer are in the mold opening, and
wherein the second vertical portion of the channel layer is outside the mold opening.

14. The semiconductor device of claim 13, wherein the channel layer on one of lower corners of the contact structure.

15. The semiconductor device of claim 11, wherein the bit line includes a horizontal extension and a vertical protrusion protruding from the horizontal extension,
wherein the vertical protrusion of the bit line corresponds to the first vertical portion of the channel layer, and
wherein the vertical protrusion of the bit line is in contact with the first vertical portion of the channel layer in the mold opening.

16. A semiconductor device comprising:
a substrate;
a bit line including a horizontal extension that extends in a first horizontal direction on the substrate and a vertical protrusion that protrudes from the horizontal extension in a vertical direction;
a channel layer comprising a first vertical portion that extends in the vertical direction on the vertical protrusion of the bit line, a horizontal portion that extends in the first horizontal direction on an upper surface of the first vertical portion, and a second vertical portion that extends in the vertical direction on an upper surface of the horizontal portion;
a gate dielectric layer in contact with an inner sidewall of the first vertical portion of the channel layer and a lower surface of the horizontal portion of the channel layer;
a word line on the gate dielectric layer, wherein the word line extends in a second horizontal direction that intersects the first horizontal direction;
a mold layer in contact with an outer sidewall of the first vertical portion of the channel layer and a sidewall of the horizontal portion of the channel layer;
a contact structure in contact with the mold layer, the horizontal portion of the channel layer, and the second vertical portion of the channel layer;
a dielectric spacer on sidewalls of the contact structure, wherein the dielectric spacer includes a plurality of spacer layers; and
a capacitor structure on the contact structure,
wherein the first horizontal direction and the second horizontal direction are parallel with an upper surface of the substrate, and
wherein the vertical direction is perpendicular to the upper surface of the substrate.

17. The semiconductor device of claim 16, wherein the plurality of spacer layers comprises first spacer layers in contact with inner sidewalls of the contact structure, second spacer layers in contact with outer sidewalls of the contact structure, and a third spacer layer spaced apart from the inner sidewalls of the contact structure by the first spacer layers, and
wherein a length in the vertical direction of one of the first spacer layers is less than a length in the vertical direction of one of the second spacer layers.

18. The semiconductor device of claim 17, wherein at least one of the first spacer layers is in contact with the second vertical portion of the channel layer.

19. The semiconductor device of claim 17, wherein the second spacer layers are in contact with an upper surface of the mold layer.

20. The semiconductor device of claim 17, wherein the mold layer includes a plurality of mold dielectric layers stacked in the vertical direction, and
wherein an uppermost mold dielectric layer from among the plurality of mold dielectric layers and the second spacer layers include a same material.
